(19) United States
(12) Patent Application Publication
(10) Pub. No.: US 2019/0378910 A1
(43) Pub. Date: Dec. 12, 2019

(54) SEMICONDUCTOR STRUCTURE AND MANUFACTURING METHOD FOR SAME

(71) Applicant: Shanghai Huali Integrated Circuit Mfg. Co., Ltd., Shanghai (CN)

(72) Inventors: Yang SONG, Shanghai (CN); Changfeng WANG, Shanghai (CN); Duanquan LIAO, Shanghai (CN)

(21) Appl. No.: 16/191,456

(22) Filed: Nov. 15, 2018

(30) Foreign Application Priority Data
Jun. 7, 2018 (CN) 201810581546.9

(51) Int. Cl. H01L 29/49; H01L 29/78; H01L 29/06; H01L 29/16; H01L 29/161; H01L 21/762; H01L 21/764; H01L 21/02; H01L 21/311

(52) U.S. Cl. CPC H01L 29/4991; H01L 29/7838; H01L 29/0649; H01L 29/16; H01L 29/161; H01L 21/76289; H01L 21/02532; H01L 21/0217; H01L 21/0228; H01L 21/02164; H01L 21/02274; H01L 21/02236; H01L 21/31116; H01L 21/764

(57) ABSTRACT

The present disclosure provides a semiconductor structure and a manufacturing method for the semiconductor structure. The semiconductor structure manufactured according to the manufacturing method provided in the present disclosure comprises a substrate and a gate formed on the substrate, and a silicon epitaxial layer is formed on the substrate at two sides of the gate; and a side surface of the gate is provided with a first side wall, with a gap being provided between the first side wall and the silicon epitaxial layer, and a surface of the first side wall further comprises a second side wall, with the second side wall covering the gap, so that there is an air gap between the first side wall and the silicon epitaxial layer.

### CROSS-REFERENCES TO RELATED APPLICATIONS

The present application claims priority to Chinese Patent Application No. 201810581546.9, filed on Jun. 7, 2018, entitled “SEMICONDUCTOR STRUCTURE AND MANUFACTURING METHOD FOR SAME”, which is incorporated by reference herein for all purposes.

### TECHNICAL FIELD

The present disclosure relates to the field of semiconductors, and in particular to the field of semiconductors of silicon-on-insulator.

### BACKGROUND OF THE DISCLOSURE

Since the disclosure of integrated circuits by Dr. Jack Kilby of Texas Instruments in early years, scientists and engineers have made numerous disclosures and improvements in semiconductor devices and processes. Over 50 years, the dimension of semiconductors have been significantly reduced, which translates into an increasing processing speed and decreasing power consumption. To date, the development of semiconductors has largely followed Moore's Law, which roughly states that the number of transistors in dense integrated circuits doubles about every two years. At present, semiconductor processes are developing toward below 20 nm, and some companies are embarking on 14 nm processes. Just to provide a reference herein, a silicon atom is about 0.2 nm, which means that the distance between two separate components manufactured by a 20 nm process is about only one hundred silicon atoms.

Semiconductor device manufacturing has therefore become increasingly challenging and advancing toward the physically possible limit. With the continuous reduction in the size of super-large-scale integrated circuits, the limitations on processes and materials properties are increasingly significant, such that it is increasingly difficult to reduce the size of planar transistors. Correspondingly, a fully depleted silicon-on-insulator (FDSOI) device is considered to be a kind of novel potential planar device due to low consumption and also the characteristics of being able to simplify production processes. Fully depleted silicon-on-insulator has an ultra-thin insulation layer, namely a buried oxide layer. The buried oxide layer can effectively limit the electrons flowing from a source to a drain, so as to greatly reduce drain currents flowing from a channel to a substrate; moreover, by means of applying body bias, an FDSOI transistor can rapidly run under a low voltage, so as to substantially improve energy efficiency.

With the advance of semiconductor technologies, the size of transistors are continuously reduced, circuits are also more and more intensive, and the number of connections of conductors in circuits is continuously increased, such that a resistance-capacitance delay (RC delay) phenomenon caused by metal connection lines would influence the operation speed of elements, and becomes a main factor for the limited signal transmission speed in circuits in 28 nm and more advanced technology.

The signal transmission speed in circuits depends on the product of a parasitic resistance (R) and a parasitic capacitance (C),

$$Device speed ∝ \frac{1}{R \times C}$$

where R is the resistance of a metal interconnection conductive line, and C is the parasitic capacitance.

The parasitic resistance of a circuit is mainly from the resistance of a metal interconnection conductive line, and the use of a copper line can effectively reduce the parasitic resistance.

The parasitic capacitance of a circuit is related to a dielectric constant and a geometrical dimension of an insulator,

$$C = ɛ \frac{S}{d}$$

where c is a dielectric constant, S is a plate area, and d is a plate spacing.

In terms of reducing the parasitic capacitance, because of process limitations, it is difficult to reduce the parasitic capacitance value by means of geometry changes at present.

Therefore, there is an urgent need for a semiconductor structure and a manufacturing method for the semiconductor structure, which can effectively reduce the parasitic capacitance of a circuit, so as to improve the performance of a semiconductor device.

### BRIEF SUMMARY OF THE DISCLOSURE

A brief summary on one or more embodiments is given below to provide the basic understanding for these embodiments. This summary is not an exhaustive overview of all the contemplated embodiments and is neither intended to indicate critical or decisive elements of all embodiments nor to attempt to define the scope of any or all embodiments. Its sole purpose is to present some concepts of one or more embodiments in a simplified form as a preface for a more detailed description presented later.

In order to solve the problem mentioned above to reduce the parasitic capacitance of a circuit, The present disclosure provides a semiconductor structure, comprising a substrate and a gate formed on the substrate, and a silicon epitaxial layer is formed on the substrate at two sides of the gate; and a side surface of the gate is provided with a first side wall, with a gap being provided between the first side wall and the silicon epitaxial layer, and a surface of the first side wall further comprises a second side wall, with the second side wall covering the gap, so that there is an air gap between the first side wall and the silicon epitaxial layer.

As the semiconductor structure described above, the first side wall further comprises an extending part located on a surface of the substrate, the silicon epitaxial layer adjoins the extending part, and the width of the extending part is equal to the width of the air gap.

As the semiconductor structure described above, the extending part has a width ranging from 4 to 8 nanometres.

As the semiconductor structure described above, the first side wall has a thickness ranging from 3 to 6 nanometres, and the second side wall has a thickness ranging from 20 to 30 nanometres.

As the semiconductor structure described above, the silicon epitaxial layer has a thickness ranging from 15 to 30 nanometres, and the height of the air gap is associated with the thickness of the silicon epitaxial layer.

As the semiconductor structure described above, the material of the second side wall is TEOS or PETEOS.

As the semiconductor structure described above, the substrate is a composite substrate, comprising a silicon base layer, a buried oxide layer and a silicon surface layer, and the buried oxide layer is located between the silicon base layer and the silicon surface layer, and the gate is formed on the silicon surface layer.

As the semiconductor structure described above, for an N-type device, the silicon epitaxial layer is made of a silicon material, and for a P-type device, the silicon epitaxial layer is made of a silicon-germanium material.

The present disclosure further provides a manufacturing method for a semiconductor structure, comprising: providing a substrate; forming a gate on the substrate; forming a first side wall on a side surface of the gate; epitaxially growing a silicon epitaxial layer on a surface of the substrate at two sides of the gate, with a gap being provided between the silicon epitaxial layer and the first side wall; and forming a second side wall on a side surface of the first side wall, with the second side wall covering the gap, so that an air gap is formed between the first side wall and the silicon epitaxial layer.

As the manufacturing method described above, the method further comprises: after the step of forming the first side wall, forming a dummy side wall on the side surface of the first side wall, and the silicon epitaxial layer epitaxially grows adjacent to the surface of the substrate in a region of the dummy side wall; and removing the dummy side wall, so as to form the gap between the silicon epitaxial layer and the first side wall.

As the manufacturing method described above, the steps of forming the first side wall and the dummy side wall further comprise: forming a side wall layer covering the gate and the surface of the substrate; forming a sacrificial layer covering the surface of the side wall layer; and etching the side wall layer and the sacrificial layer to retain the side wall layer and the sacrificial layer at the two sides of the gate, so as to form the first side wall and the dummy side wall, and the first side wall comprises an extending part located on the surface of the substrate, and the width of the extending part is equal to the thickness of the dummy side wall.

As the manufacturing method described above, the first side wall has a thickness ranging from 3 to 6 nanometres, and the dummy side wall has a thickness ranging from 4 to 8 nanometres.

As the manufacturing method described above, the first side wall is formed by means of atomic layer deposition; and the dummy side wall is formed by means of hollow cathode discharge deposition.

As the manufacturing method described above, after the step of depositing the first side wall, the method further comprises: performing a surface oxidation treatment on the first side wall.

As the manufacturing method described above, the step of forming a second side wall further comprises: depositing an oxide on the surfaces of the first side wall and the silicon epitaxial layer, with the oxide covering the gap, so that an air gap is formed between the first side wall and the silicon epitaxial layer; and etching back the oxide, so as to form a second side wall.

As the manufacturing method described above, the oxide is deposited by means of chemical vapor deposition or plasma-enhanced chemical vapor deposition.

As the semiconductor structure described above, the material of the oxide is TEOS or PETEOS.

As the manufacturing method described above, the step of etching back the oxide further comprises: etching back the oxide by means of dry etching, so as to form the second side wall having a thickness ranging from 20 to 30 nanometres.

As the manufacturing method described above, the provided substrate is a composite substrate, comprising a silicon base layer, a buried oxide layer and a silicon surface layer, and the buried oxide layer is located between the silicon base layer and the silicon surface layer, and the gate is formed on the silicon surface layer.

As the manufacturing method described above, the silicon epitaxial layer having a thickness ranging from 15 to 30 nanometres is epitaxially grown, and for an N-type device, the silicon epitaxial layer is made of a silicon material, and for a P-type device, the silicon epitaxial layer is made of a silicon-germanium material.

In a 28 nanometres and below node manufacturing process, the process for a gate side wall is particularly important, because it defines the position of a gate source/drain region relative to a gate, and decides the magnitude of the parasitic capacitance between a contact hole (CT) and the gate with regard to the following process for the contact hole. The semiconductor structure and the manufacturing method for same provided in the present disclosure reduce, by means of forming an air gap between two layers of side walls on the basis of this processing platform of fully depleted silicon-on-insulator, the dielectric value (K) of the material of the side wall, so that when a low K-value material (K<3) is used as a barrier substance between circuits, the parasitic capacitance value can be effectively reduced, which is, corresponding to the present disclosure, effectively reducing the parasitic capacitance between a contact hole and a gate. Therefore, the electrical properties of the semiconductor device are improved.

### BRIEF DESCRIPTION OF THE DRAWINGS

FIGS. 1A and 2-9 show a structural schematic diagram in a manufacturing process of one embodiment of a semiconductor structure provided in the present disclosure.

FIG. 1B shows a structural schematic diagram of a gate of one embodiment of a semiconductor structure provided in the present disclosure.

FIGS. 10-19 show a structural schematic diagram in a manufacturing process of another embodiment of the semiconductor structure provided in the present disclosure.

### REFERENCE SIGNS

Substrate 100, 200
Silicon base layer 101, 201
Buried oxide layer 102, 202
Silicon surface layer 103, 203
Gate 110, 210
Interlayer insulation layer 111
High-K dielectric layer 112
Capping layer 113
Polycrystalline silicon gate 114
Hard mask layer 115, 116
First side wall 120, 220
Side wall oxide layer 121, 221
Sacrificial layer 130, 230
Silicon epitaxial layer 140, 141, 142, 240
Air gap 150, 250
Second side wall 160, 260
Oxide 161, 261

### DETAILED DESCRIPTION OF THE DISCLOSURE

The present disclosure is described below in detail in conjunction with the accompanying drawings and particular embodiments. It is noted that the embodiments described in conjunction with the accompanying drawings and particular embodiments are merely exemplary, and should not be construed as any limitation on the scope of protection of the present disclosure.

The present disclosure relates to a semiconductor process and device. More specifically, the embodiments of the present disclosure provide a semiconductor device. The semiconductor device comprises a substrate and a gate on the substrate, and silicon epitaxial layers are formed at two sides of the gate, a side surface of the gate is provided with a first side wall, with a gap being provided between the first side wall and the silicon epitaxial layer, and a surface of the first side wall is further provided with a second side wall for covering the gap, so that there is an air gap between the first side wall and the silicon epitaxial layer. By forming the air gap between the side wall and the silicon epitaxial layer, the dielectric values K of the materials of the side walls are reduced, and the parasitic capacitance value is effectively reduced. The present disclosure also provides other embodiments.

The reader is cautioned as to all files and documents which are filed at the same time as this specification and which are open for the public to consult, and the contents of all such files and documents are incorporated herein by reference. Unless directly stated otherwise, all features disclosed in this specification (including any appended claims, the abstract, and the accompanying drawings) may be replaced by other features serving the same, equivalent, or similar purpose. Therefore, unless expressly stated otherwise, each feature disclosed is only one example of a group of equivalent or similar features.

Note that when used, the flags left, right, front, back, top, bottom, front, back, clockwise, and counterclockwise are used for convenience purposes only and do not imply any specific fixed direction. In fact, they are used to reflect the relative position and/or direction between various parts of an object.

As used herein, the terms “over . . . ”, “under . . . ”, “between . . . and . . . ”, and “on . . . ” means the relative position of that layer relative to another layer. Likewise, for example, a layer that is deposited or placed over or under another layer may be in direct contact with another layer or there may be one or more intervening layers. In addition, a layer that is deposited or placed between layers may be in direct contact with the layers or there may be one or more intervening layers. In contrast, a first layer “on” a second layer is in contact with the second layer. In addition, a relative position of a layer relative to another layer is provided (assuming that film operations of deposition, modification, and removal are performed in relative to a starting substrate, without considering the absolute orientation of the substrate).

As state above, in a 28 nanometres and below node manufacturing process, the process for a gate side wall is particularly important, because it defines the position of a gate source/drain region relative to a gate, and decides the magnitude of the parasitic capacitance between a contact hole (CT) and the gate with regard to the following process for the contact hole. In terms of reducing the parasitic capacitance, because of process limitations, it is difficult to reduce the parasitic capacitance value by means of geometry changes at present.

Therefore, the present disclosure provides a semiconductor structure and a manufacturing method for the semiconductor structure, which can effectively reduce the parasitic capacitance of a circuit, so as to improve the performance of a semiconductor device.

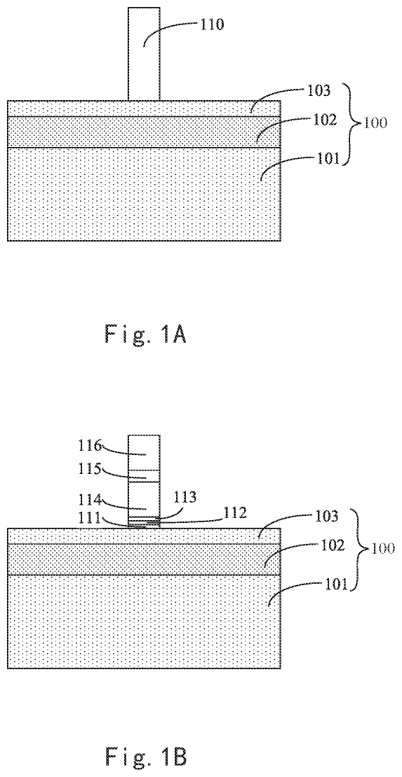

FIGS. 1A and 2-9 show a structural schematic diagram in a manufacturing process of one embodiment of a semiconductor structure provided in the present disclosure. These diagrams provide examples only and should not unduly limit the scope of the claims. Those skilled in the art will appreciate that there are many variations, alternatives, and modifications. Depending on implementations, one or more steps may be added, removed, repeated, rearranged, modified, replaced, and/or alternated without affecting the scope of the claims.

As shown in FIG. 1A, a gate 110 is formed on a substrate 100. Specifically, the substrate 100 provided in the present disclosure is a composite substrate, comprising a silicon base layer 101, a buried oxide layer 102 and a silicon surface layer 103, so as to finally form a fully depleted silicon-on-insulator (FDSOI) device. The FDSOI has an ultra-thin insulation layer, namely the buried oxide layer 102. The buried oxide layer 102 can effectively limit the electrons flowing from a source to a drain, so as to greatly reduce drain currents flowing from a channel to a substrate; moreover, by means of applying body bias, an FDSOI transistor can rapidly run under a low voltage, so as to substantially improve energy efficiency.

Specifically, in one embodiment, as shown in FIG. 1B, the formed gate 110 further comprises an interlayer insulation layer 111, a high-K dielectric layer 112, a capping layer 113, a polycrystalline silicon gate 114 and two hard mask layers 115 and 116 on a surface of the polycrystalline silicon gate 114. More specifically, the interlayer insulation layer 111 is an oxide; the high-K dielectric layer 112 is a hafnium oxide material; the capping layer 113 is a titanium nitride material; and the polycrystalline silicon gate 114 is a dummy gate, which would be removed in the subsequent processes and is filled with a gate material, such as metal gate tungsten, in a corresponding position; and in one embodiment, the polycrystalline silicon gate 114 has a height of 55 nanometres. The hard mask layer 115 is a silicon nitride material, and the hard mask layer 116 is a silicon oxide material.

A person skilled in the art should know that the above-mentioned structure regarding the gate 110 is merely exemplary, and the semiconductor structure and the gate structure 110 formed by means of the manufacturing process for same, and the manufacturing process for the gate 110 can use the existing or future techniques as needed, but not limited to the above-mentioned examples.

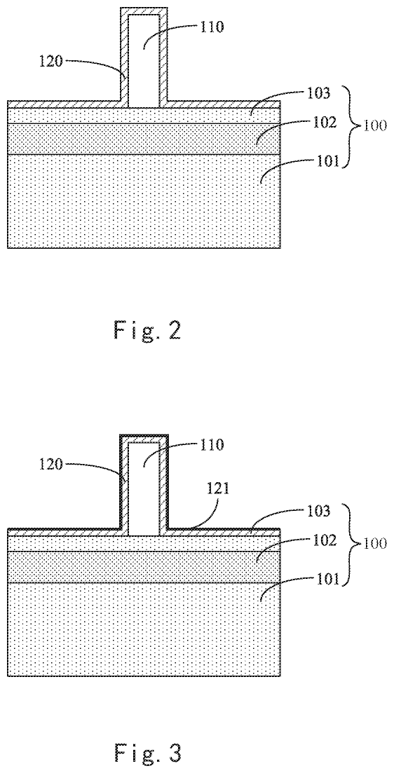

FIG. 2 shows a schematic diagram of forming a first side wall 120 on a surface of a substrate 100, with a gate 110 formed, and the gate 110. Specifically, the first side wall 120 can be formed by means of atomic layer deposition (ALD). The material of the first side wall 120 can be silicon nitride, and in one embodiment, the deposited first side wall 120 has a thickness of 4 nanometres. The thickness of the first side wall 120 decides the distance from a position, where ion injection in a source/drain extension region is performed, to the gate, and the increase in the thickness of the first side wall can effectively increase a channel length so as to relieve the short channel effect. Nevertheless, the thickness of the first side wall 120 would influence the overlap capacitance between the source/drain extension region and the gate and thus influence a gate turn-on voltage and electric leakage, and therefore, the thickness of the first side wall may be controlled within a certain range. In the present disclosure, comprehensively considering the impact of the thickness of the first side wall 120 on the electrical properties of a gate turn-on voltage, electric leakage, etc., the thickness of the first side wall is set between 3 and 6 nanometres, and in the above-mentioned embodiment, the thickness of the deposited first side wall 120 is possibly 4 nanometres.

After the step of forming the first side wall 120, a surface oxidation treatment is performed on the formed first side wall 120. FIG. 3 shows a structural schematic diagram of forming a side wall oxide layer 121 on the first side wall 120 after performing the surface oxidation treatment. Between the time when the first side wall 120 is deposited and the time a sacrificial layer of a second side wall is (subsequently) deposited, a process of performing ion injection on the source/drain extension region is further comprised, and the process specifically comprises photo-resist material depositing, photo-etching, ion injecting, etc. The surface oxidation treatment after the deposition of the first side wall 120 is mainly to prevent photo-resist material deposition from causing photo-resist nitrogen poisoning and thus influencing the photo-etching effect.

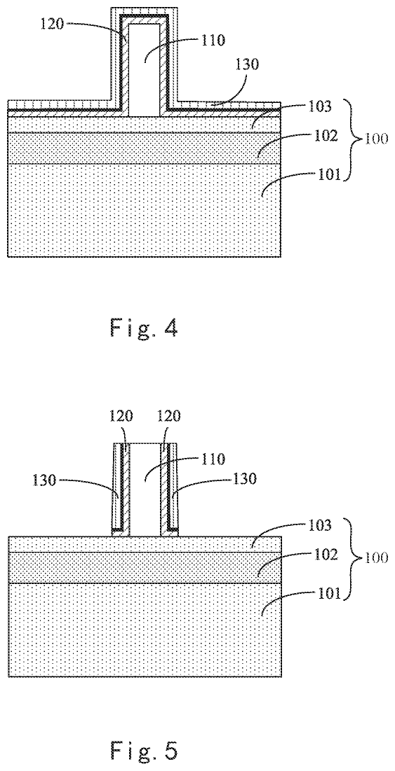

FIG. 4 shows a structural schematic diagram of forming, after performing the oxidation treatment on the first side wall 120, a sacrificial layer 130 (a dummy side wall) of the second side wall on the surface of the first side wall. In one embodiment, specifically, the sacrificial layer 130 having a thickness of 6 nanometres is deposited by means of hollow cathode discharge deposition (HCD), and the sacrificial layer 130 is a hard mask silicon nitride layer. The thickness of the sacrificial layer defines the distance between the gate and the source/drains the distance between the gate and the source/drain being set between 4 and 8 nanometres, and therefore the thickness of the sacrificial layer 130 ranges from 4 to 8 nanometres, possibly 6 nanometres in the above-mentioned embodiment.

FIG. 5 shows a structural schematic diagram after etching the first side wall 120 and the sacrificial layer 130. Specifically, in the embodiment as shown in FIG. 5, the first side wall 120 and the sacrificial layer 130 at two sides of the gate are retained. In the photo-etching step of this process, it is only necessary to use one photo mask plate, and saving a photo mask plate is one of important parts in saving costs in a semiconductor fabrication process. Moreover, a region of the surface of the substrate 100 where the first side wall 120 and the sacrificial layer 130 are removed in the etching process also corresponds to a silicon active region which is to be subsequently grown by the silicon epitaxial layer.

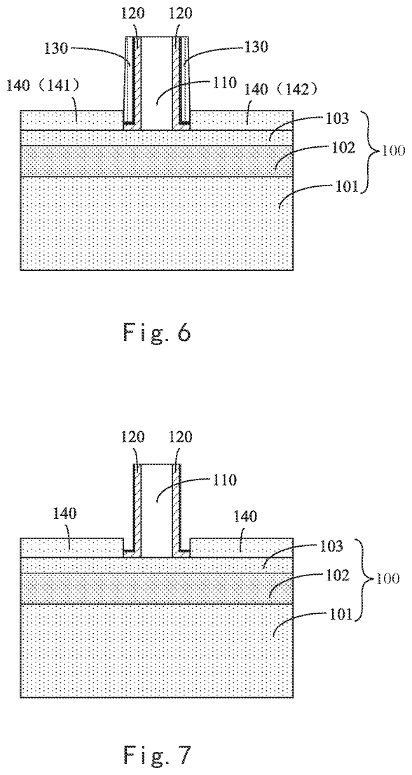

FIG. 6 shows a structural schematic diagram of forming a silicon epitaxial layer 140 in a silicon active region on the surface of the substrate 100. Specifically, in one embodiment, the silicon epitaxial layer 141 is a source region, and the silicon epitaxial layer 142 is a drain region. The silicon epitaxial layer has a certain thickness, which can be within the range of 15 to 30 nanometres. Since the substrate 100 provided in the present disclosure is a composite substrate, the thickness of a silicon surface layer 103 on SOI wafer is generally about 12 nanometres, and the silicon surface layer 103 may not form a traditional sigma shape, a source/drain region needs to be formed in the epitaxially grown silicon epitaxial layer 140. The thickness of the silicon epitaxial layer 140 would influence the intensity of a stress applied in a channel. Theoretically, the thicker the silicon epitaxial layer, the larger the stress, and the better the performance of the device. However, because much thicker silicon epitaxial layer 140 is subject to subsequent manufacturing processes and may not be grown, the thickness of the silicon epitaxial layer 140 is controlled between the 15 and 30 nanometres in the present disclosure.

In the above-mentioned embodiment, before an epitaxial process, removing a natural oxidation layer from the surface of the silicon surface layer 103 is further comprised. Specifically, dilute hydrofluoric (DHF) with a concentration of 200:1 can be used as a remover for the natural oxidation layer.

In the above-mentioned embodiment, for an N-type semiconductor device, the silicon epitaxial layer 140 is made of a silicon material. For a P-type semiconductor device, the silicon epitaxial layer 140 is made of a silicon-germanium material, so as to better improve the electrical property of the silicon epitaxial layer 140. Moreover, as stated above, the silicon epitaxial layer 140 grows on the surface of the silicon substrate 100 with the first side wall 120 and the sacrificial layer 130 removed, and therefore, the silicon epitaxial layer 140 adjoins the first side wall 120 and the sacrificial layer 130 retained on the side surface of the gate 110.

FIG. 7 shows a structural schematic diagram of removing the sacrificial layer 130 (a dummy side wall) of the second side wall after forming the silicon epitaxial layer 140. Specifically, in an embodiment where the sacrificial layer 130 is a hard mask silicon nitride material, a thermal phosphoric acid wetting process can be used to remove the sacrificial layer 130 with the duration time of 1 to 2 minutes. As shown in FIG. 7, after the sacrificial layer 130 is removed, it is found that an extending part is further comprised on the surface of the substrate 100 with the first side wall 120 located. It can be seen from the foregoing processes that the extending part adjoins the silicon epitaxial layer 140, and the width of the extending part is equal to the thickness of the sacrificial layer 130. In the above-mentioned embodiment, the width of the extending part ranges from 4 to 8 nanometres, possibly 6 nanometres. Furthermore, after the sacrificial layer 130 is removed, it can be seen from FIG. 7 that a gap is provided between the first side wall 120 and the silicon epitaxial layer 140, and the width of the gap is also equal to the thickness of the sacrificial layer 13.

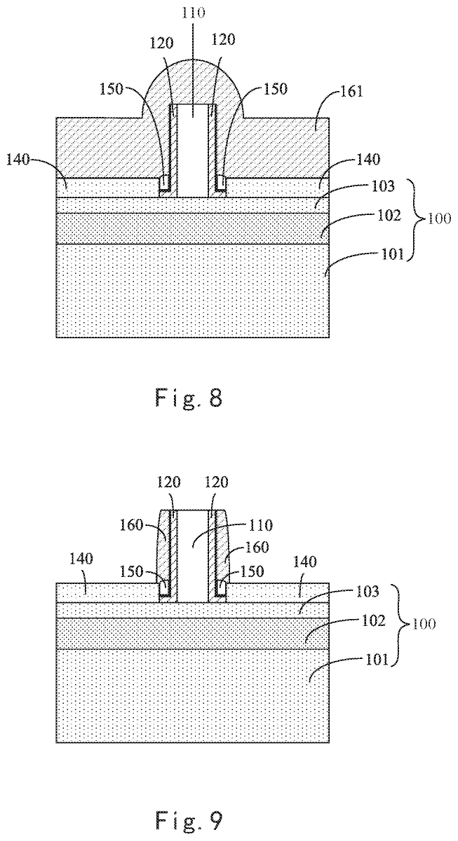

FIG. 8 shows a structural schematic diagram of depositing an oxide 161 on the surface of the first side wall 120 and the silicon epitaxial layer 140 after removing the sacrificial layer 130. In this deposition process, the formed oxide 161 covers the gap, so that an air gap 150 is formed between the first side wall 120 and the silicon epitaxial layer 140. As stated above, the width of the air gap 150 is consistent with the thickness of the sacrificial layer 130, and the height of the air gap 150 is associated with the thickness of the silicon epitaxial layer 140 and the thickness of the first side wall 120.

In the above-mentioned embodiment, an oxide with a poor fillibility is used for deposition, and the deposition can be performed by means of chemical vapor deposition or plasma-enhanced chemical vapor deposition. Specifically, the oxide with a poor fillibility includes but is not limited to Tetraethoxysilane (TEOS, Si(OC2H5)4) or plasma enhanced Tetraethoxysilane (PETEOS). For example, by taking TEOS as a raw material, where chemical vapor deposition or plasma-enhanced chemical vapor deposition is used to form the oxide, Si(OC2H5)4--->SiO2+by-products, the two deposition methods have a relatively simple process, but have a poor coverage rate in a small-sized region because of rapid deposition rate, such that the air gap 150 is formed between the gate and the source/drain region.

FIG. 9 shows a schematic diagram of finally forming a second side wall 160 of one embodiment of a semiconductor structure provided in the present disclosure. After the oxide 161 as shown in FIG. 8 is formed, it is also necessary to etch back the oxide 161, so as to form the second side wall 160. The finally formed second side wall 160 has a thickness ranging from 20 to 30 nanometres, and the thickness of the second side wall 160 defines the distance from a position, where subsequent ion injection in a source/drain region is performed, to the gate 110, thereby influencing the final electrical performance.

Subsequent operations should be performed so as to form a usable transistor device after the second side wall 160 is formed. The subsequent steps at least comprise: doping source/drain regions of various devices by means of photo-etching and doping steps; growing NiSi in the source/drain regions of the devices; and etching a contact hole, depositing a stop layer and depositing an intermediate medium layer, etc., which will not be described herein.

By means of the above-mentioned steps, in the semiconductor structure provided in the present disclosure, between the gate and the source/drain, dielectric values K of the materials of the side walls are changed via an air gap formed between the first side wall and the silicon epitaxial layer and covered by the second side wall, thereby achieving the effect of effectively reducing the parasitic capacitance between a contact hole and the gate as a result of a lower K value of the air gap, so as to further improve the electrical properties of the semiconductor device.

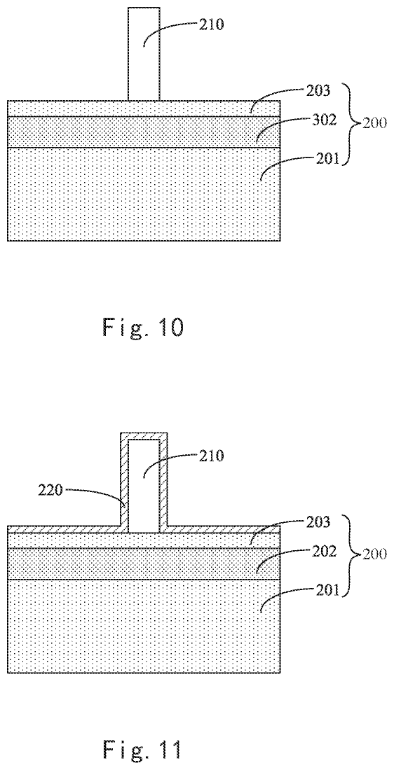

FIGS. 10-19 show a structural schematic diagram in a manufacturing process of another embodiment of the semiconductor structure provided in the present disclosure. As shown in FIG. 10, a gate 210 is formed on a substrate 200. Specifically, the substrate 200 is a composite substrate, comprising a silicon base layer 201, a buried oxide layer 202 and a silicon surface layer 203, so as to finally form a fully depleted silicon-on-insulator device. The gate 210 may be the specific structure of the gate 110 as shown in FIG. 1B, and may also be the other specific gate structures formed by using other existing or future fabrication processes as needed.

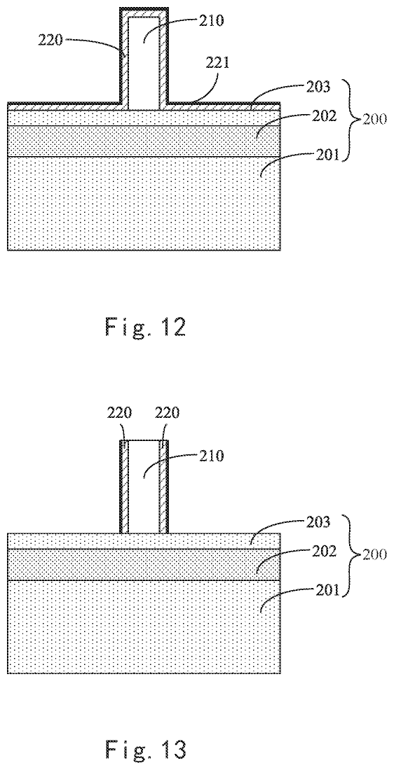

FIG. 11 shows a schematic diagram of forming a first side wall 220 on a surface of a substrate 200, with the gate 210 formed, and the gate 210. FIG. 12 shows a structural schematic diagram after a surface oxidation treatment is performed on the first side wall 220 to form a side wall oxide layer 221. With regard to the specific steps, process parameters and structural characteristics, reference is made to the embodiments as shown in FIGS. 2 and 3, which will not be described herein.

After the surface oxidation treatment is performed on the first side wall 220, in this embodiment, a process of etching the first side wall 220 is further comprised. FIG. 13 shows a structural schematic diagram after etching. As shown in FIG. 13, after a series of steps of at least photo-resist material deposition, photo-etching, etching, etc., first side walls 220 at two sides of the gate 210 are retained, while the redundant first side wall 220 on the surface of the substrate 200.

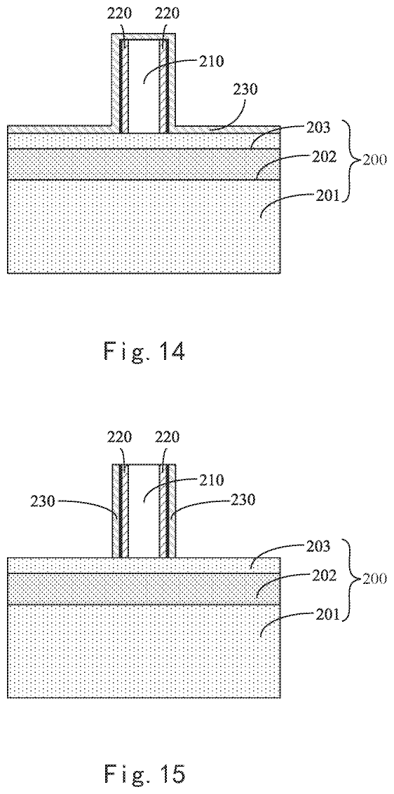

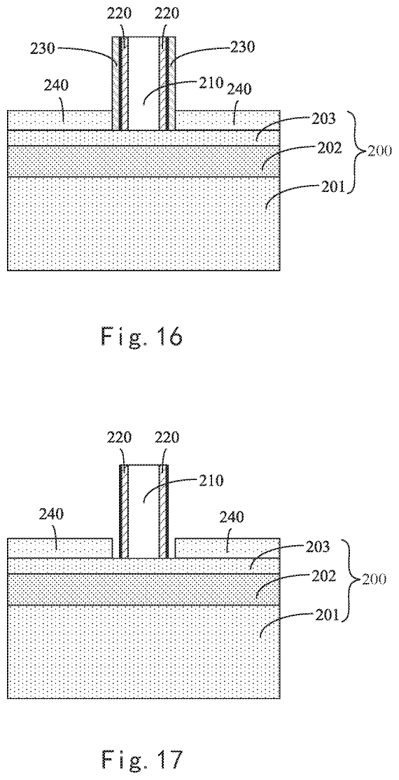

FIG. 14 shows a structural schematic diagram of forming a sacrificial layer 230 (a dummy side wall) of the second side wall on the surface of the first side wall 220 and the substrate 200. FIG. 15 shows a structural schematic diagram after etching the sacrificial layer 230. FIG. 16 shows a structural schematic diagram of forming a silicon epitaxial layer 240 in a silicon active region on the surface of the substrate 200. FIG. 17 shows a structural schematic diagram of the sacrificial layer 230 (a dummy side wall) with the second side wall removed after the silicon epitaxial layer 240 is formed. With regard to the specific steps, process parameters and structural characteristics, reference is made to the embodiments as shown in FIGS. 4-7, which will not be described herein.

As shown in FIG. 17, after the sacrificial layer 230 is removed, a gap is formed between the first side wall 220 and the silicon epitaxial layer 240, and since the first side wall 220 does not have an extending part on the surface of the substrate 200 in this embodiment, the gap has a larger depth than that in the embodiment as shown FIG. 7.

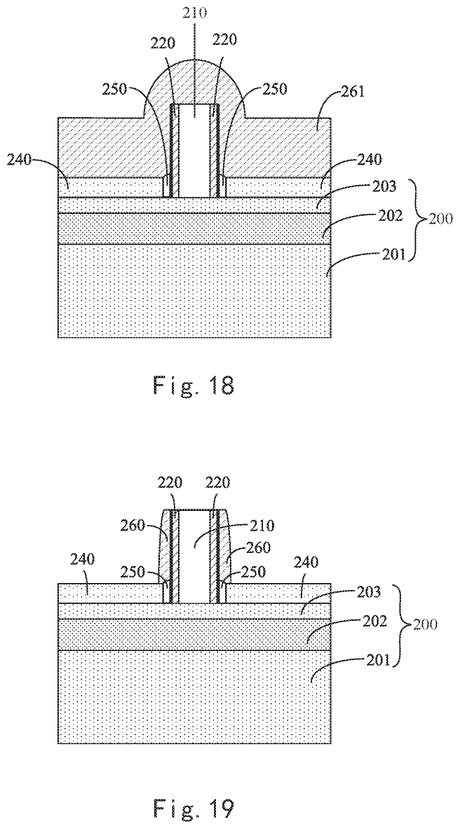

FIG. 18 shows a structural schematic diagram of depositing an oxide 261 on the surface of the first side wall 220 and the silicon epitaxial layer 240 after removing the sacrificial layer 230. In this deposition process, the formed oxide 261 covers the gap, so that an air gap 250 is formed between the first side wall 220 and the silicon epitaxial layer 240. As stated above, since the gap has a larger depth, a gap 250 formed in this step has a larger height than the air gap 150 in the embodiment shown in FIG. 8, and the height of the air gap 250 is associated with a growth thickness of the silicon epitaxial layer 240.

FIG. 19 shows a schematic diagram of finally forming a second side wall 260 of another embodiment of a semiconductor structure provided in the present disclosure. After the oxide 261 as shown in FIG. 18 is formed, it is also necessary to etch back the oxide 261, so as to form the second side wall 260. The finally formed second side wall 260 has a thickness ranging from 20 to 30 nanometres, and the thickness of the second side wall 260 defines the distance from a position, where subsequent ion injection in a source/drain region is performed, to the gate 210, thereby influencing the final electrical performance.

By means of the above-mentioned steps, in the semiconductor structure provided in the present disclosure, between the gate and the source/drain, dielectric values K of the materials of the side walls are changed via an air gap formed between the first side wall and the silicon epitaxial layer and covered by the second side wall, thereby achieving the effect of effectively reducing the parasitic capacitance between a contact hole and the gate as a result of a lower K value of the air gap, so as to further improve the electrical properties of the semiconductor device. Since the height of the air gap is larger in the above-mentioned embodiment, the dielectric K value of the material of the side wall is more preferably reduced.

Therefore, the embodiments of the method for manufacturing a side wall with a semiconductor structure having a gap and the structure thereof have been described. Although the present disclosure has been described with respect to certain exemplary embodiments, it will be apparent that various modifications and changes may be made to these embodiments without departing from the more general spirit and scope of the disclosure. Accordingly, the specification and the accompanying drawings are to be regarded in an illustrative rather than a restrictive sense.

It is to be understood that this description is not intended to explain or limit the scope or meaning of the claims. In addition, in the detailed description above, it can be seen that various features are combined together in a single embodiment for the purpose of simplifying the disclosure. The method of the present disclosure should not be interpreted as reflecting the intention that the claimed embodiments require more features than those expressly listed in each claim. Rather, as reflected by the appended claims, an inventive subject matter lies in being less than all features of a single disclosed embodiment. Therefore, the appended claims are hereby incorporated into the detailed description, with each claim standing on its own as a separate embodiment.

One embodiment or embodiments mentioned in this description is/are intended to be, combined with a particular feature, structure, or characteristic described in the embodiment, included in at least one embodiment of a circuit or method. The appearances of phrases in various places in the specification are not necessarily all referring to a same embodiment.

What is claimed is:

1. A semiconductor structure, comprising:
a substrate and a gate formed on the substrate, wherein a silicon epitaxial layer is formed on the substrate at two sides of the gate; and each side surface of the gate is provided with a first side wall, with a gap being provided between the first side wall and the silicon epitaxial layer, and a surface of the first side wall further comprises a second side wall, with the second side wall covering the gap, so that there is an air gap between the first side wall and the silicon epitaxial layer.

2. The semiconductor structure of claim 1, wherein the first side wall further comprises an extending part located on a surface of the substrate, the silicon epitaxial layer adjoins the extending part, and the width of the extending part is equal to the width of the air gap.

3. The semiconductor structure of claim 2, wherein the extending part has a width ranging from 4 to 8 nanometres.

4. The semiconductor structure of claim 1, wherein the first side wall has a thickness ranging from 3 to 6 nanometres, and the second side wall has a thickness ranging from 20 to 30 nanometres.

5. The semiconductor structure of claim 1, wherein the silicon epitaxial layer has a thickness ranging from 15 to 30 nanometres, and the height of the air gap is associated with the thickness of the silicon epitaxial layer.

6. The semiconductor structure of claim 1, wherein the material of the second side wall is TEOS or PETEOS.

7. The semiconductor structure of claim 1, wherein the substrate is a composite substrate, comprising a silicon base layer, a buried oxide layer and a silicon surface layer, wherein the buried oxide layer is located between the silicon base layer and the silicon surface layer, and the gate is formed on the silicon surface layer.

8. The semiconductor structure of claim 1, wherein for an N-type device, the silicon epitaxial layer is made of a silicon material, and for a P-type device, the silicon epitaxial layer is made of a silicon-germanium material.

9. A manufacturing method for a semiconductor structure, comprising:
providing a substrate;
forming a gate on the substrate;
forming a first side wall on each side surface of the gate;
epitaxially growing a silicon epitaxial layer on a surface of the substrate at two sides of the gate, with a gap being provided between the silicon epitaxial layer and the first side wall; and
forming a second side wall on a side surface of the first side wall, with the second side wall covering the gap, so that an air gap is formed between the first side wall and the silicon epitaxial layer.

10. The manufacturing method of claim 9, further comprising:
after the step of forming the first side wall, forming a dummy side wall on the side surface of the first side wall, wherein the silicon epitaxial layer epitaxially grows on a surface of the substrate adjacent to the dummy side wall; and
removing the dummy side wall, so as to form the gap between the silicon epitaxial layer and the first side wall.

11. The manufacturing method of claim 10, wherein the steps of forming the first side wall and the dummy side wall further comprise:
forming a side wall layer covering the gate and the surface of the substrate;
forming a sacrificial layer covering the surface of the side wall layer; and
etching the side wall layer and the sacrificial layer to retain the side wall layer and the sacrificial layer at the two sides of the gate, so as to form the first side wall and the dummy side wall, wherein the first side wall comprises an extending part located on the surface of the substrate, and the width of the extending part is equal to the thickness of the dummy side wall.

12. The manufacturing method of claim 10, wherein the first side wall has a thickness ranging from 3 to 6 nanometres, and the dummy side wall has a thickness ranging from 4 to 8 nanometres.

13. The manufacturing method of claim 10, wherein the first side wall is formed by means of atomic layer deposition; and
the dummy side wall is formed by means of hollow cathode discharge deposition.

14. The manufacturing method of claim 10, characterized by after the step of depositing the first side wall, further comprising: performing a surface oxidation treatment on the first side wall.

15. The manufacturing method of claim 9, wherein the step of forming a second side wall further comprises: depositing an oxide on the surfaces of the first side wall and the silicon epitaxial layer, with the oxide covering the gap, so that an air gap is formed between the first side wall and the silicon epitaxial layer; and
etching back the oxide, so as to form a second side wall.

16. The manufacturing method of claim 15, wherein the oxide is deposited by means of chemical vapor deposition or plasma-enhanced chemical vapor deposition.

17. The manufacturing method of claim 15, wherein the material of the oxide is TEOS or PETEOS.

18. The manufacturing method of claim 15, wherein the step of etching back the oxide further comprises: etching back the oxide by means of dry etching, so as to form the second side wall having a thickness ranging from 20 to 30 nanometres.

19. The manufacturing method of claim 9, wherein the provided substrate is a composite substrate, comprising a silicon base layer, a buried oxide layer and a silicon surface layer, wherein the buried oxide layer is located between the silicon base layer and the silicon surface layer, and the gate is formed on the silicon surface layer.

20. The manufacturing method of claim 9, further comprising epitaxially growing the silicon epitaxial layer that has a thickness ranging from 15 to 30 nanometres, wherein
for an N-type device, the silicon epitaxial layer is made of a silicon material, and for a P-type device, the silicon epitaxial layer is made of a silicon-germanium material.
